(19) United States
(12) Patent Application Publication
(10) Pub. No.: US 2013/0313252 A1
(43) Pub. Date: Nov. 28, 2013

(54) PROTECTIVE SHELL

(71) Applicant: Mike CHAN, Sugar Land, TX (US)

(72) Inventor: Mike CHAN, Sugar Land, TX (US)

(21) Appl. No.: 13/846,687

(22) Filed: Mar. 18, 2013

Related U.S. Application Data
(60) Provisional application No. 61/652,215, filed on May 27, 2012.

(51) Int. Cl. H05K 5/00

(52) U.S. Cl. CPC H05K 5/0004
USPC 220/4.02

(57) ABSTRACT

A protective shell applicable to a handheld electric apparatus includes a main body and a fixing auxiliary. The main body has a front face and a back face opposite to each other, and the main body has a first accommodating slot and a second accommodating slot. The first accommodating slot is located at the front face, and used for accommodating the handheld electric apparatus. The second accommodating slot is located at the back face, and the second accommodating slot includes a first sidewall and a second sidewall opposite to each other. The first sidewall has a first sliding rail, and the second sidewall has a second sliding rail. The fixing auxiliary is at least disposed at one of the sliding rails in a removable manner.

### CROSS-REFERENCES TO RELATED APPLICATIONS

This Application claims priority from U.S. Provisional Patent Application Ser. No. 61/652,215, filed on May 25, 2012, which Application is incorporated by reference herein.

### BACKGROUND

1. Technical Field

The disclosure relates to a protective shell, and particularly to a protective shell applicable to a handheld electric apparatus.

2. Related Art

With the development of protective shells (sheaths), of various portable electric apparatuses, an impact-proof bag, a metal protective shell, a shock-proof and beautiful silica gel protective sheath, a colorful plastic protective sheath, a leather sheath and a transparent acryl protective shell which are collision-proof and impact-proof, are seen frequently in the current market.

These protective shells have a certain protective effect, but when some protective shells are used, an operation can be performed only after the portable electric apparatus is taken out, so the use is inconvenient. For example, the portable electric apparatus easily drops out due to carelessness in the procedure of placing the portable electric apparatus in or taking the portable electric apparatus out, so protection fails to be provided to the portable electric apparatus.

Additionally, most current portable electric apparatuses have a self shooting or Internet surfing function. However, even if a portable electric apparatus is provided with a protective shell, whenever a user holds the portable electric apparatus with a single hand to handle transactions, it is still required to design a light and thin portable electric apparatus to be held stably or design a portable electric apparatus with rounded corners, so as to prevent the portable electric apparatus from slipping off.

Furthermore, when a user uses an earphone to listen to multimedia, peripherals such as an earphone are still required to be additionally equipped with a pocket body for accommodation.

Consequently, how to mount a protective shell on a handheld electric apparatus so as to bring convenience to a user and have good protectiveness is a topic to be urgently improved by the inventor of the disclosure and persons engaged in the technical field of the relevant industry.

### SUMMARY

In view of this, the disclosure proposes a protective shell, applicable to a handheld electric apparatus, and the protective shell includes a main body and a fixing auxiliary. The main body has a front face and a back face opposite to each other, and the main body has a first accommodating slot and a second accommodating slot. The first accommodating slot is located at the front face, and used for accommodating the handheld electric apparatus. The second accommodating slot is located at the back face, and the second accommodating slot includes a first sidewall and a second sidewall opposite to each other. The first side wall includes a first sliding rail, and the second side wall includes a second sliding rail. The fixing auxiliary disposed at at least one of the first sliding rail and the second sliding rail in a removable manner.

The disclosure may use a first accommodating slot on a protective shell to accommodate a handheld electric apparatus, a fixing auxiliary (for example, a strap) is disposed at a second accommodating slot. Through sliding the strap along the sidewall, the strap can be adjusted to be located at a suitable position to fix a carry-on article of a user, such as a personal card, a business card, an earphone or another mobile phone. Or, when the user uses a photo shooting function, the strap can assist in holding the handheld electric apparatus. Further, a mobile power supply may also be disposed by use of the second accommodating slot, and charge the handheld electric apparatus. Additionally, a back cover may also be pivoted in the second accommodating slot, and the second accommodating slot may be partitioned into a plurality of accommodating spaces, so the user places carry-on articles conveniently according to categories; furthermore, the inside of the back cover may be a mirror surface to be used and favorably carried by the user, and the mirror surface is protected by the hard material of the outside of the back cover, so as to prevent the mirror surface from rupturing due to collision.

The detailed features and advantages of the disclosure are described below in great detail through the following embodiments, the content of the detailed description is sufficient for those skilled in the art to understand the technical content of the disclosure and to implement the disclosure there accordingly. Based upon the content of the specification, the claims, and the drawings, those skilled in the art can easily understand the relevant objectives and advantages of the disclosure.

### BRIEF DESCRIPTION OF THE DRAWINGS

The disclosure will become more fully understood from the detailed description given herein below for illustration only, and thus not limitative of the disclosure, wherein:

FIG. 1A is an exploded view (1) of a protective shell according to an embodiment;

FIG. 1B is an exploded view (2) of a protective shell according to an embodiment;

FIG. 1C is a three-dimensional view of a protective shell according to an embodiment;

FIG. 1D is a three-dimensional view of a protective shell according to another embodiment;

FIG. 2A is a schematic application view (1) of a protective shell according to an embodiment;

FIG. 2B is a schematic application view (2) of a protective shell according to an embodiment;

FIG. 2C is a schematic application view of a protective shell according to another embodiment;

FIG. 2D is a schematic application view of a protective shell according to still another embodiment;

FIG. 2E is a three-dimensional view (1) of a protective shell according to the other embodiment;

FIG. 2F is a three-dimensional view (2) of a protective shell according to the other embodiment;

FIG. 3 is a schematic application view of a protective shell according to an embodiment;

FIG. 4 is a schematic application view of a protective shell according to another embodiment;

FIG. 5A is a schematic charging view of a protective shell according to an embodiment;

FIG. 5B is a schematic charging view of a protective shell according to another embodiment;

FIG. 6 is a schematic charging view of a protective shell according to the other embodiment;

FIG. 7A is a schematic application view of a fix auxiliary according to an embodiment;

FIG. 7B is a schematic application view of a fix auxiliary according to another embodiment;

FIG. 7C is a schematic application view of a fix auxiliary according to still another embodiment; and

FIG. 7D is a schematic application view of a fix auxiliary according to the other embodiment.

### DETAILED DESCRIPTION

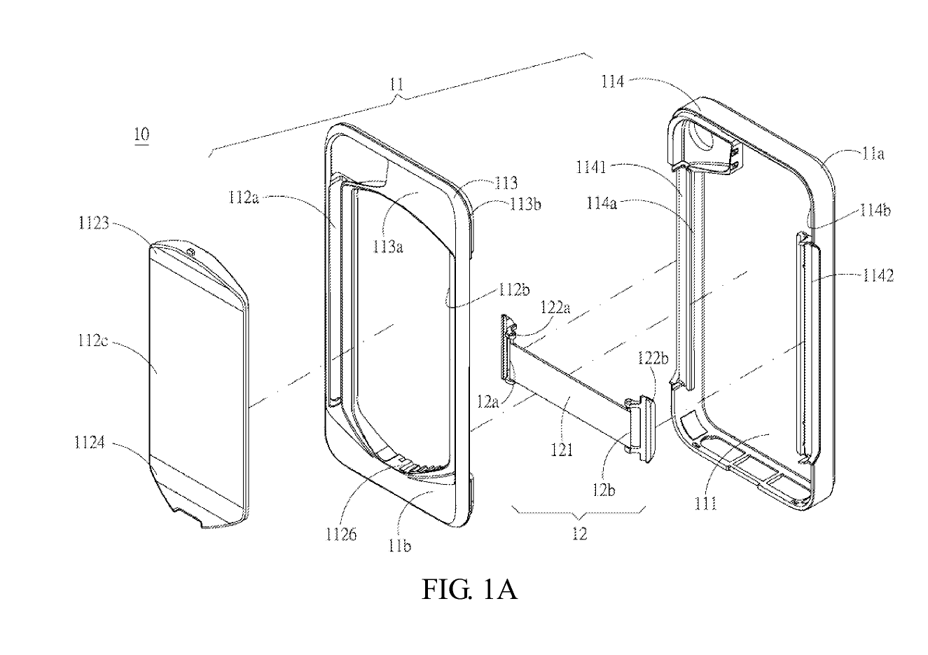

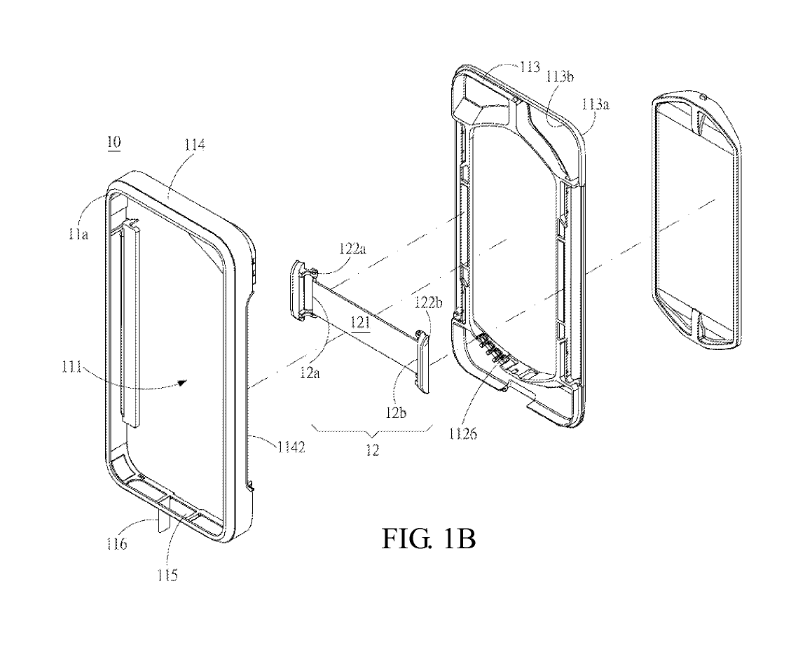

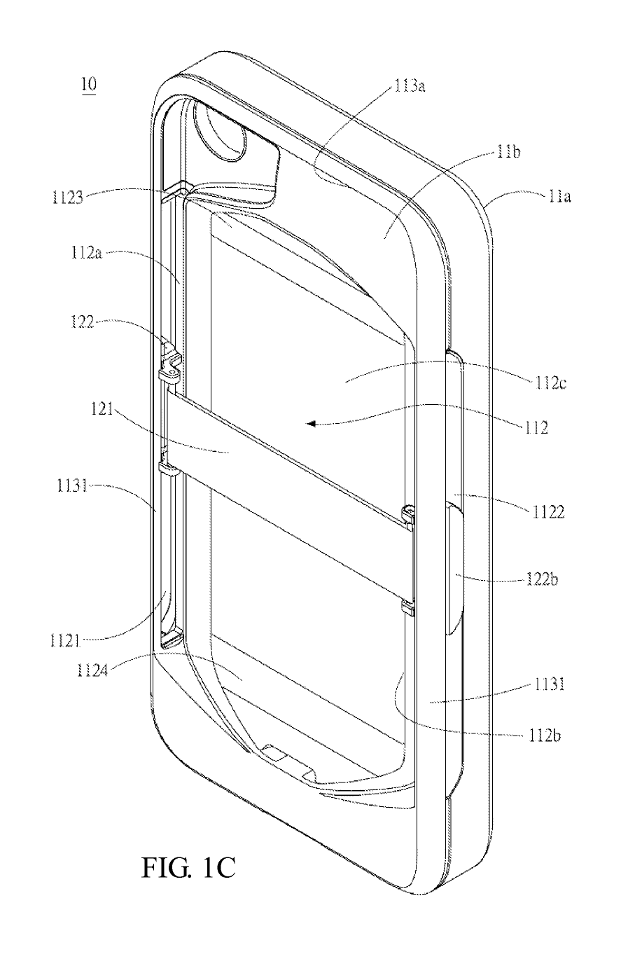

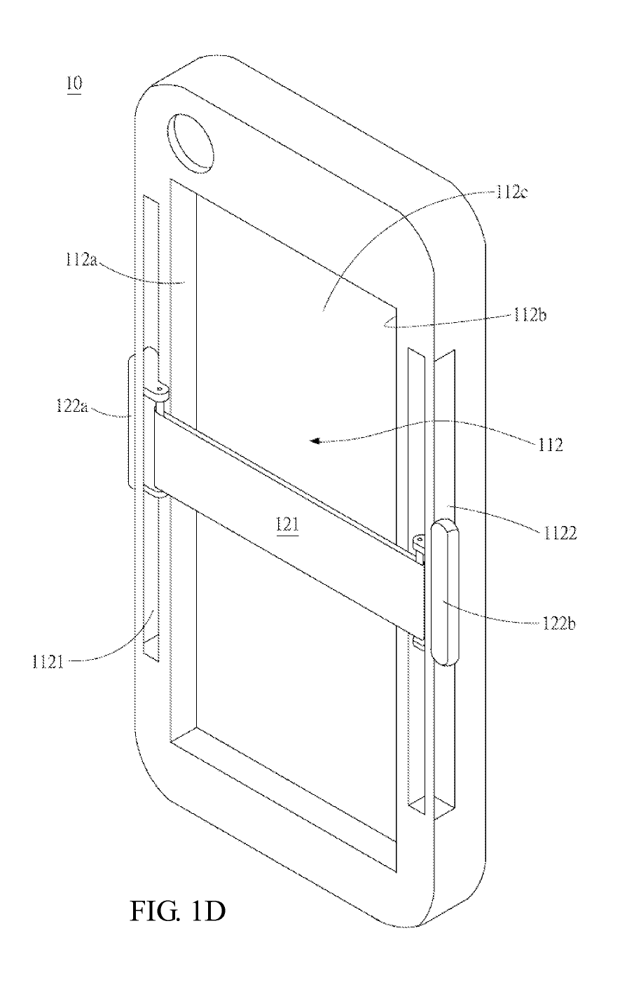

FIG. 1A and FIG. 1B are exploded views of a protective shell according to an embodiment. FIG. 1C is a three-dimensional view of a protective shell according to an embodiment. The protective shell 10 wholly is approximately in a shape of cuboid.

Please refer to FIG. 1A to FIG. 1C, in which the protective shell 10 has a main body 11 and a fixing auxiliary (such as a strap 12). The main body 11 has a front face 11a and a back face 11b opposite to each other, and the main body 11 has a first accommodating slot 111 and a second accommodating slot 112. The first accommodating slot 111 is located at the front face 11a, and the second accommodating slot 112 is located at the back face 11b.

As shown in FIG. 1A and FIG. 1B, the main body 11 further has a rear shell 113 and a front shell 114. The rear shell 113 has a first face 113a and a second face 113b opposite to each other, and the first face 113a is disposed with the second accommodating slot 112. The front shell 114 may be a frame body, and the front shell 114 is connected to the periphery of the second face 113b of the rear shell 113 to form the first accommodating slot 111.

Two sidewalls 114a/114b of the front shell 114 opposite to each other respectively have notches 1141/1142, and a first sliding rail 1121 and a second sliding rail 1122 are respectively formed between the two notches 1141/1142 and the second face 113b of the rear shell 113. That is to say, the two sidewalls 114a/114b respectively abut against the second face 113b of the rear shell 113 so as to respectively form the first sliding rail 1121 and the second sliding rail 1122 at the two notches. Based on this, on a first sidewall 112a and a second sidewall 112b opposite to each other of the second accommodating slot 112, the first sidewall 112a has the first sliding rail 1121, and the second sidewall 112b has the second sliding rail 1122. Here, each of the notches 1141/1142 has an elongated shape. Each of the both ends of the notches 1141/1142 is a specific shape, such that the shape of the notch 1141/1142 can be, for example, rectangular, elliptic or trapezoidal approximately. The first sliding rail 1121 and the second sliding rail 1122 substantially can be elongated holes.

The fixing auxiliary (herein, the strap 12) is disposed at at least one of the first sliding rail 1121 and the second sliding rail 1122 in a removable manner. The strap 12 has a first end 12a and a second end 12b opposite to each other, the first end 12a is disposed at the first sidewall 112a in a slidable manner, and the second end 12b is disposed at the second sidewall 112b in a slidable manner.

In an embodiment, the strap 12 further has an elastic strap 121 and two stop blocks 122 connected to two ends of the elastic strap 121, one (122a) of the two stop blocks 122 is located at the first end 12a of the strap 12, the other (122b) of the two stop blocks 122 is located at the second end 12b of the strap 12, the elastic strap 121 passes through the first sliding rail 1121 and the second sliding rail 1122, and the two stop blocks 122 respectively abut against outsides of the first sliding rail 1121 and the second sliding rail 1122.

In some implementation aspects, the first sliding rail 1121 and the second sliding rail 1122 may be a strip rail groove, and the two stop blocks 122 may be a strip-shaped slide block.

In some implementation aspects, the second accommodating slot 112 may be a polygonal accommodating space. As shown in FIG. 1C, the bottom surface 112c of the second accommodating slot 112 is tetragonal, the slot notch of the second accommodating slot 112 is hexagonal, but embodiments are not limited thereto, the slot notch of the second accommodating slot 112 is quadrilateral (as shown in FIG. 1D).

In some implementation aspects, the depth of the second accommodating slot 112 may be less than the depth of the first accommodating slot 111, so as to accommodate an article with the thickness less than the thickness of the handheld electric apparatus. However, the embodiments are not limited thereto, and the depth of the first accommodating slot 111 and the depth of the second accommodating slot 112 may be adjusted according to requirements.

In some implementation aspects, the bottom surface 112c of the second accommodating slot 112 is neighboring to the first sliding rail 1121 or the second sliding rail 1122. In other words, the depth of the second accommodating slot 112 is approximately equal to the height of the sliding rail.

Through the aforementioned protective shell 10, the user may fix an article accommodated in the second accommodating slot 112 with the aid of the strap 12, such as a card, a business card, or an earphone 80. Alternatively, the user may move the two stop blocks 122 of the strap 12 along the first sliding rail 1121 and the second sliding rail 1122, and then adjusts the strap 12 to an appropriate position, so that a finger of the user is inserted between the strap 12 and the second accommodating slot 112, so as to assist in stably holding the handheld electric apparatus.

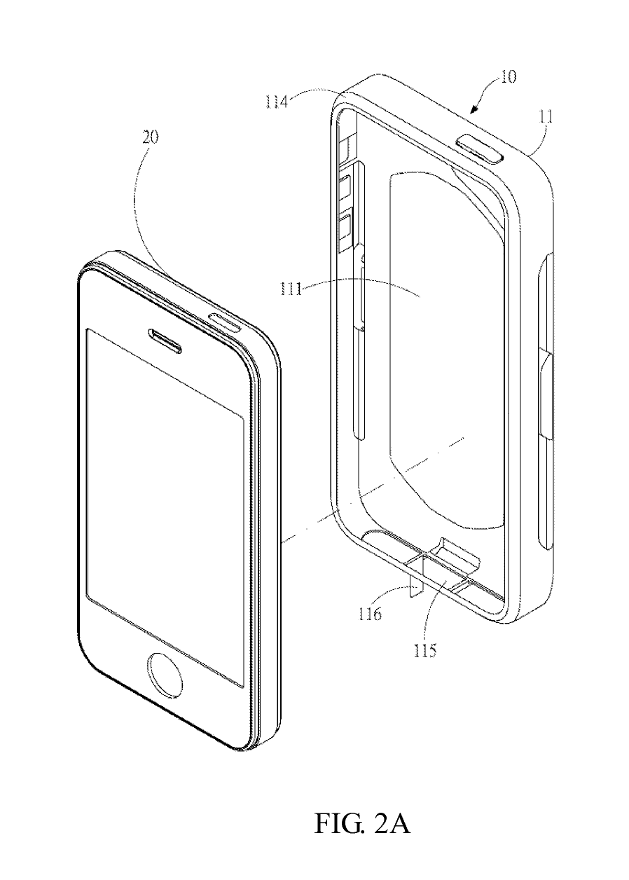

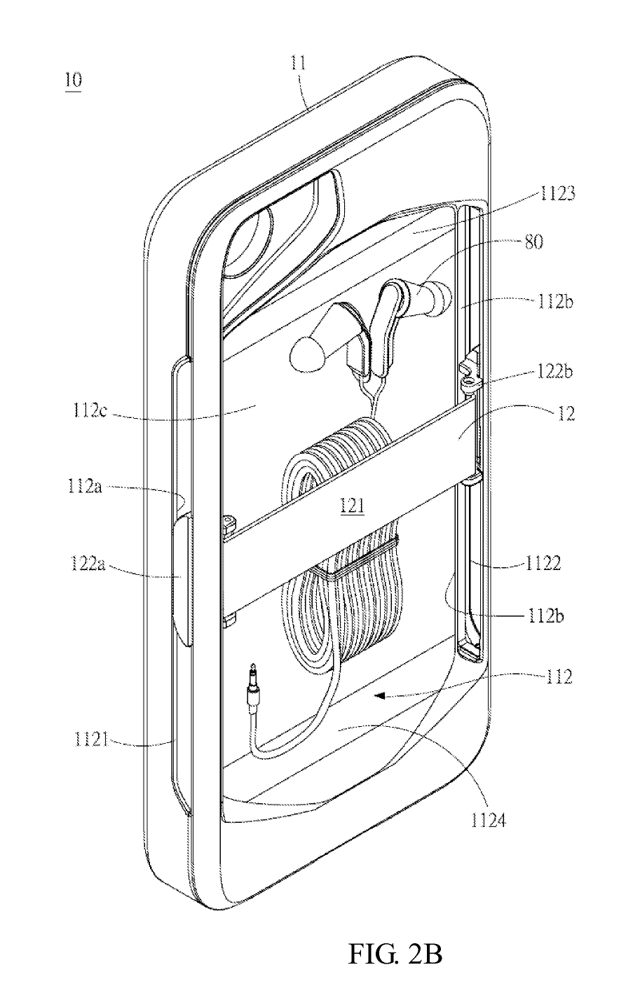

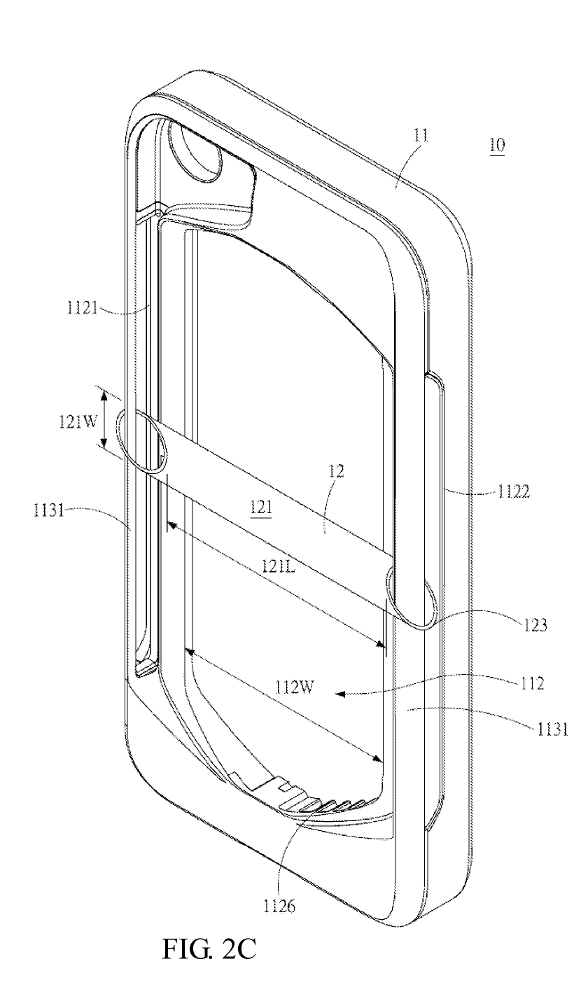

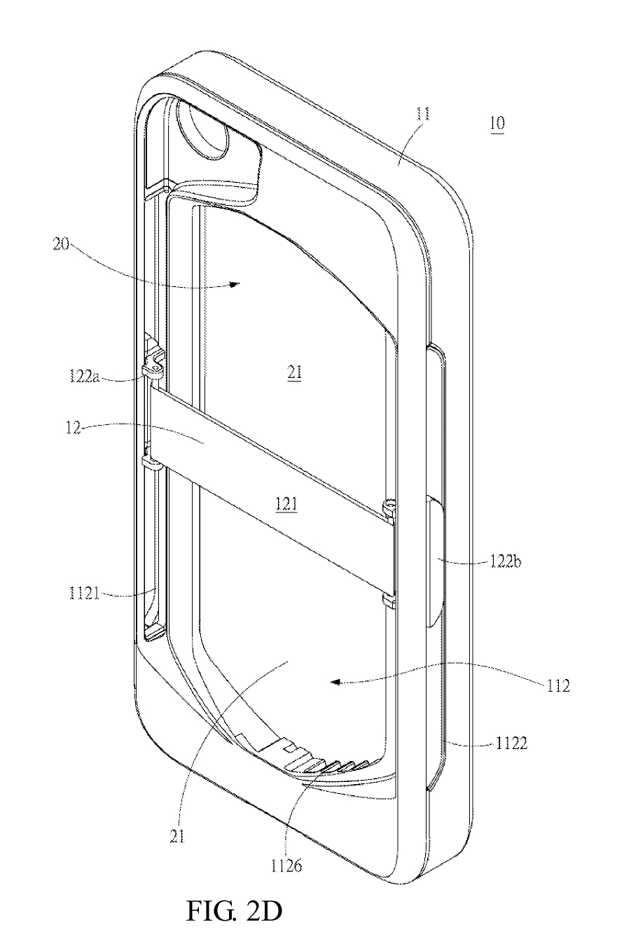

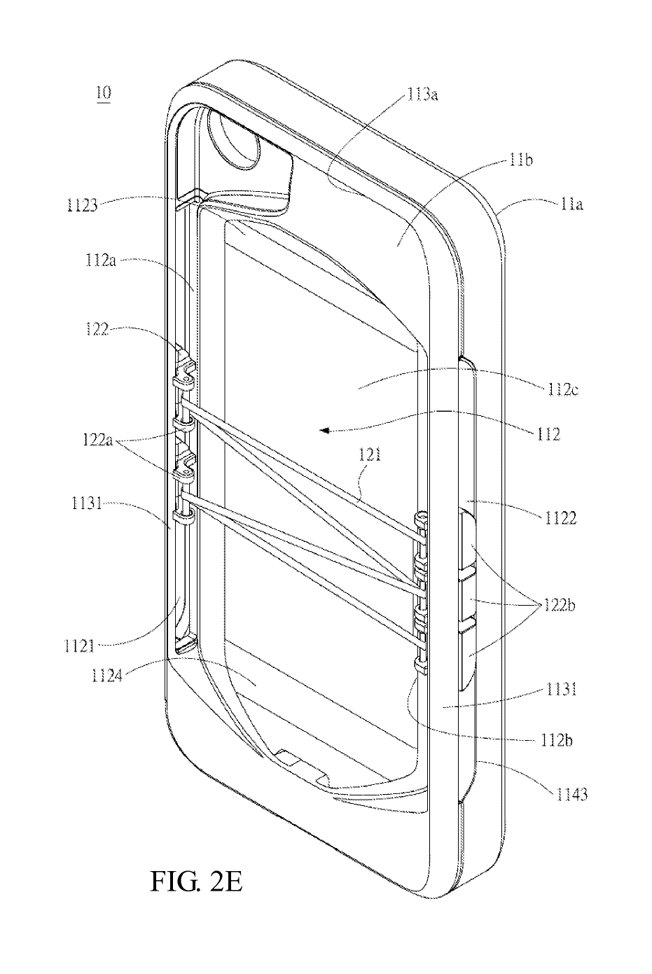

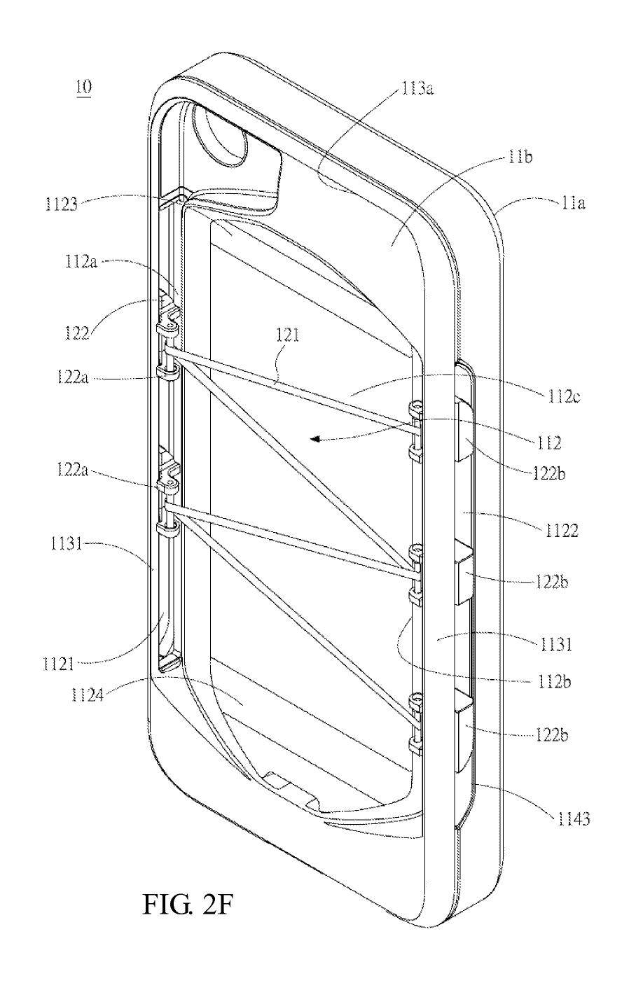

FIG. 2A to FIG. 2D are schematic application views of a protective shell 10 according to an embodiment, which are used for illustrating that the protective shell 10 may be used for accommodating the handheld electric apparatus 20 and other articles. Here, the handheld electric apparatus 20 may be an apparatus such as a mobile phone, a smart phone, a personal digital assistant (PDA), or a tablet computer.

Please refer to FIG. 2A, in which the first accommodating slot 111 is used for accommodating the handheld electric apparatus 20, and the handheld electric apparatus 20 may be embedded into the frame body of the front shell 114, so the handheld electric apparatus 20 is fixed in the protective shell 10.

The main body 11 further has an opening 115 disposed corresponding to a connecting port (e.g., charging port, audio port, etc.) of the handheld electric apparatus 20 and a dust proof cover 116 connected to the opening 115. Therefore, a connection line (such as a charging line or a data transmission line, taking the charging line as an example here), may be connected to the handheld electric apparatus 20 through the opening 115 without detaching the handheld electric apparatus 20 from the protective shell 10. When the charging line does not need to be connected, the user may clasp the dust proof cover 116, so as to protect the handheld electric apparatus 20 (for example, prevent dusts from entering the handheld electric apparatus 20 through the charging port.

In some embodiments, the main body 11 may have the opening 115 and the dust proof cover 116 corresponding to another connection port of the handheld electric apparatus 20, and the connection port is not limited to charging use.

Please refer to FIG. 2B, in which the strap 12 may fix an article placed in the second accommodating slot 112, such as an earphone 80, a card or/and a bill, so the user carries the article conveniently.

In some implementation aspects, the second accommodating slot 112 further has two slopes 1123/1124, the two slopes are respectively disposed at two ends between the first sidewall 112a and the second sidewall 112b, and the included angle between the two slopes 1123/1124 and the bottom surface 112c of the second accommodating slot 112 may be an obtuse angle. The user may place a card (such as a personal card, a payment card and an ID card), in the second accommodating slot 112, and because of the obtuse angle between the slopes 1123/1124 and the bottom surface 112c, the user may conveniently push a card located in the second accommodating slot 112 out or place a card into the second accommodating slot 112. However, the embodiment is not limited to that the connection place between the slopes 1123/1124 and the bottom surface 112c is an obtuse angle, and the connection place between the slopes 1123/1124 and the bottom surface 112c of the second accommodating slot 112 may Additionally be a right angle, a rounded corner or a curved surface.

Please refer to FIG. 2C, in which in some implementation aspects, the previously referred to stop block 122 may be replaced with a lantern ring 123, that is to say, the strap 12 has the aforementioned elastic strap 121 and two lantern rings 123 connected to two ends of the elastic strap 121. The two lantern rings 123 are respectively sleeved over two sides 1131 of the rear shell 113, and may respectively slide on the first sliding rail 1121 and the second sliding rail 1122, so as to drive the strap 12 to move.

In some implementation aspects, the length 121L of the elastic strap 121 of the strap 12 is approximately equal to the width 112W of the second accommodating slot 112, and the width 121W of the elastic strap 121 may be less than the length 121L of the elastic strap 121, or the width 121W of the elastic strap 121 may partially cover the second accommodating slot 112. The user places another handheld electric apparatus by use of the second accommodating slot 112, and protects the screen of the handheld electric apparatus with the elastic strap 121. However, the embodiment is not limited thereto, and the length of the strap 12 may be adjusted according to actual requirements.

In some implementation aspects, the aforementioned stop block 122 or lantern ring 123 may be replaced with a fastener (namely, so-called Velcro). After the strap 12 passes through the first sliding rail 1121 and the second sliding rail 1122, the Velcro sticks to and fro and the strap 12 is fixed on the first sliding rail 1121 and the second sliding rail 1122 in a slidable manner. Here, the user may adjust the bonding position of the fastener according to requirements of the user, so as to control the sliding difficulty of the strap 12, or adjust the degree of tightness of the elastic strap 121, thereby fixing the article in the second accommodating slot 112.

Please refer to FIG. 2D, in which in some implementation aspects, the bottom of the second accommodating slot 112 is hollow. Here, there is a hexagonal opening between the first accommodating slot and the second accommodating slot. When the handheld electric apparatus 20 is placed in the first accommodating slot 111, a space equivalent to the aforementioned second accommodating slot 112 may still be formed through a back face 21 of the handheld electric apparatus 20, so as to place an article. Thus, the cost of the productive shell and the weight of that can be reduced.

In some embodiments, the sidewall of the first accommodating slot 111 may be in an arc shape and is slightly elastic, so that the handheld electric apparatus 20 is embedded into the first accommodating slot 111.

FIGS. 2E and 2F are three-dimensional view of a protective shell 10 according to an embodiment, for illustrating the amount of the stop blocks 122 can be three or more. Two of the stop blocks 122 are located on the both ends of the elastic strap 121, and the other stop block(s) 122 is/are located between the both ends of the elastic strap 121. Here, FIGS. 2E and 2F are illustrating that there are two stop blocks 122a on the first sliding rail 1121 and three stop blocks 122b on the second sliding rail 1122. The stop blocks 122 are connected with each other in a removable manner (i.e., the two stop blocks 122a on the same side can be connected with each other, and the three stop blocks 122b on the same side can be connected with each other). The elastic strap 121 is connected with the stop blocks 122 on each sides of the second accommodating slot 112 in series. When the stop blocks 122 are separated (as shown in FIG. 2F), the elastic strap 121 can be distributed in a wider range than that in FIG. 2E, so that the article placed in the second accommodating slot 112 can be fixed more stably.

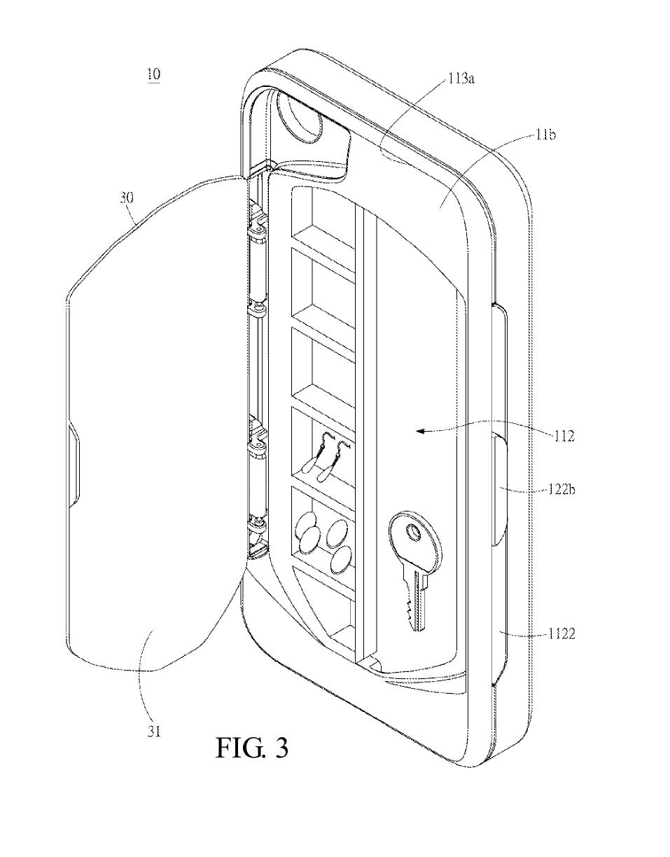

FIG. 3 is a schematic application view of a protective shell 10 according to an embodiment, which is used for illustrating that the protective shell 10 may further have a back cover 30. Please refer to FIG. 3, in which the back cover 30 is pivoted on the second accommodating slot 112, so as to cover the slot notch of the second accommodating slot 112. The second accommodating slot 112 may be provided with a division piece, which divides the second accommodating slot 112 into a plurality of grids, and the user places carry-on articles, such as a key, alternative drugs or cosmetics conveniently according to categories. Additionally, the inside 31 of the back cover 30 may be disposed with a mirror to be used by the user, or the back cover 30 may be made into a mirror surface with metal or other light reflecting materials.

In some embodiments, the back cover 30 can be fastened on the second accommodating slot 112, for example, in a magnetic or engaging manner, when covering the second accommodating slot 112.

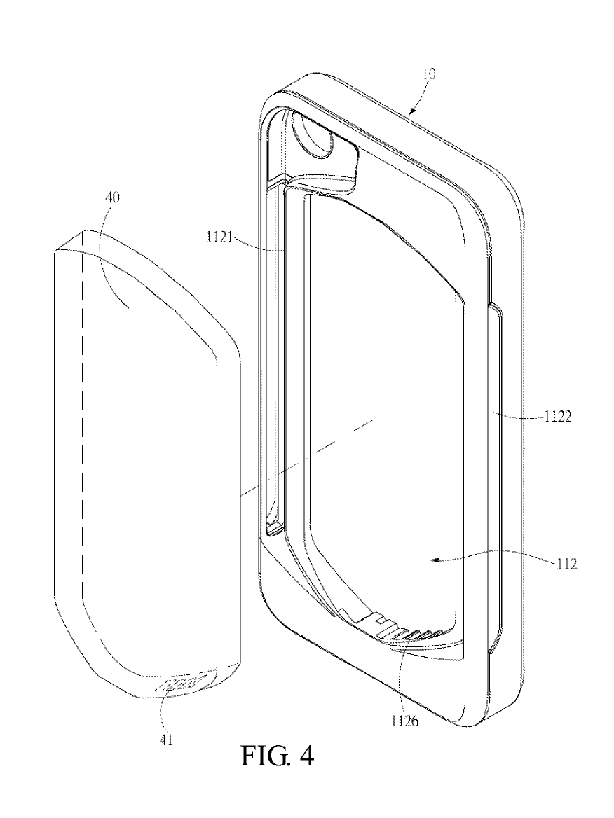

FIG. 4 is a schematic application view of a protective shell according to another embodiment.

Please refer to FIG. 4, in which the protective shell 10 may further have a rechargeable battery 40, and the rechargeable battery 40 is disposed in the second accommodating slot 112 in a removable manner. The rechargeable battery 40 includes a power supply terminal 41, the second accommodating slot 112 further has a receiving port 1126 disposed corresponding to the power supply terminal 41. Here, the shape of the rechargeable battery 40 may approximately conform to that of the second accommodating slot 112.

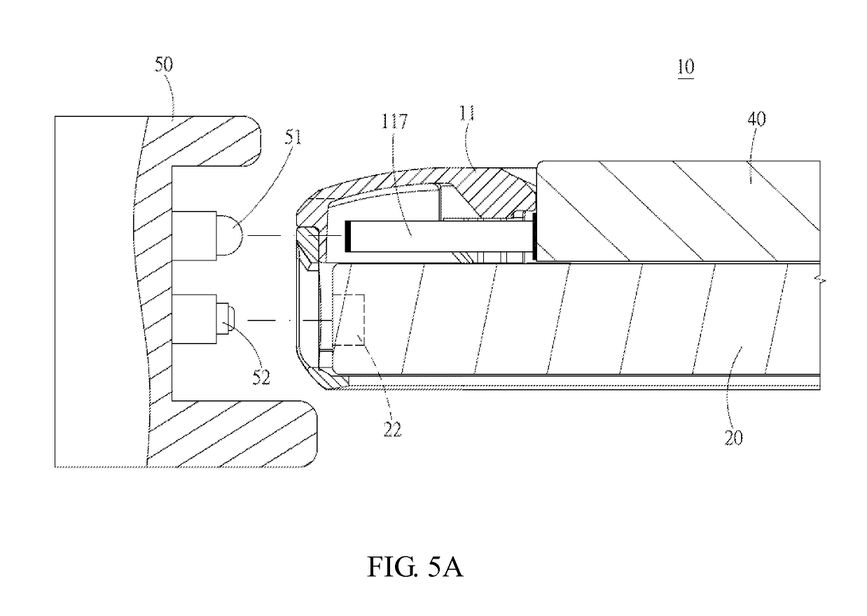

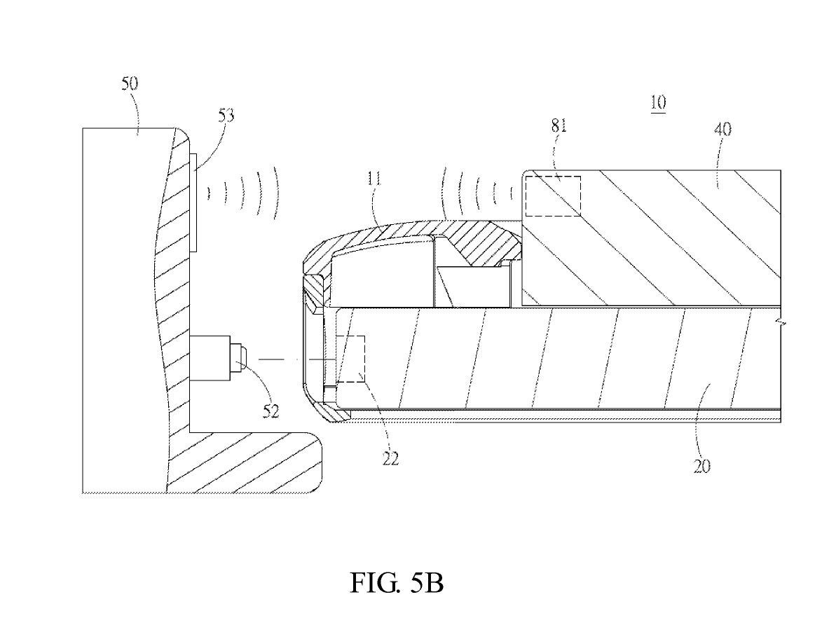

Referring to FIG. 5A, the productive shell 10 further includes a power connector 50. The main body 11 of the productive shell 10 further includes a power supply port 117, electrically connected to the receiving port 1126, so as to conduct the electrical power of the rechargeable battery 40 through the power supply port 117. The power connector 50 is used to connect with the power supply port 117 of the protective shell 10 and the charging port 22 of the handheld electric apparatus 20. That is to say, the power connector 50 includes a first connecting end 51 and a second connecting end 52. The first connecting end 51 is correspondingly connected to the power supply port 117. The second connecting end 52 is correspondingly connected to the charging port 22, so as to provide power from the first connecting end 51 to the handheld electric apparatus 20. Thus, the handheld electric apparatus 20 can receive the electrical power of the rechargeable battery 40 for charging.

Here, for example, the first connecting end 51 may be a connector met the micro USB specifications, and the second connecting end 52 may be a connector met the “Lighting” specifications of an America company—“Apple Inc”.

Referring to FIG. 5B, which illustrates a power connector 50 according to another embodiment. In addition to the wired connection as shown in FIG. 5A, the power connector 50 can use the wireless power conduction technique to provide the power from the rechargeable battery to the handheld electric apparatus 20. The protective shell 10 may include a wireless power supply module 81. The wireless power supply module 81 may in the main body 11 or the rechargeable battery 40. The power connector 50 includes the second connecting end 52 and the wireless receiver 53. The wireless power supply module 81 is connected to the receiving port 1126 to receive the electrical power of the rechargeable battery 40. The wireless receiver 53 can receive the electric power through the wireless power supply module 81 in an electromagnetic induction manner. The second connecting end 52 is correspondingly connected to the charging port 22 of the handheld electric apparatus 20, such that the electrical power received from the wireless receiver 53 can be provided to the handheld electric apparatus 20.

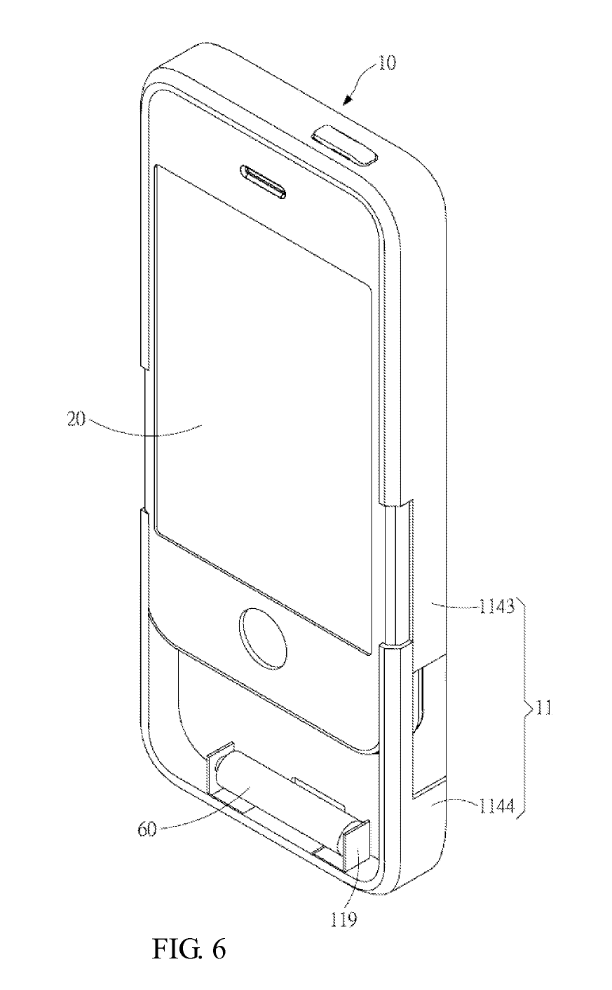

Referring to FIG. 6, in an embodiment, the front shell 114 includes a upper frame 1143 and a lower frame 1144 connected with each other in a removable manner. The front shell 114 further includes a battery holder 119 located at the inner side of the bottom of the lower frame 1144, such that the battery holder 119 can contain a primary battery 60 when the upper frame 1143 and the bottom frame 1144 are separated. The battery holder 119 is electrically connected to the power supply port 117. Thus, the power connector 50 can be used to connect with the power supply port 117 and the charging port 22 of the handheld electric apparatus 20. Therefore, when the handheld electric apparatus 20 is about out of power, the user can buy the primary battery 60 in a store for temporarily using. Here, the protective shell 10 may include a voltage regulator (not shown) for transforming the voltage output of the primary battery 60 to the voltage that the handheld electric apparatus 20 can use.

In some embodiments, the front shell 114 or the rear shell 113 may be formed by a plurality of elements; for example, the front shell 114 may be formed by the upper frame 1143 and lower frame 1144. In one embodiment, a front frame and a rear frame may form the front shell 114 (not shown).

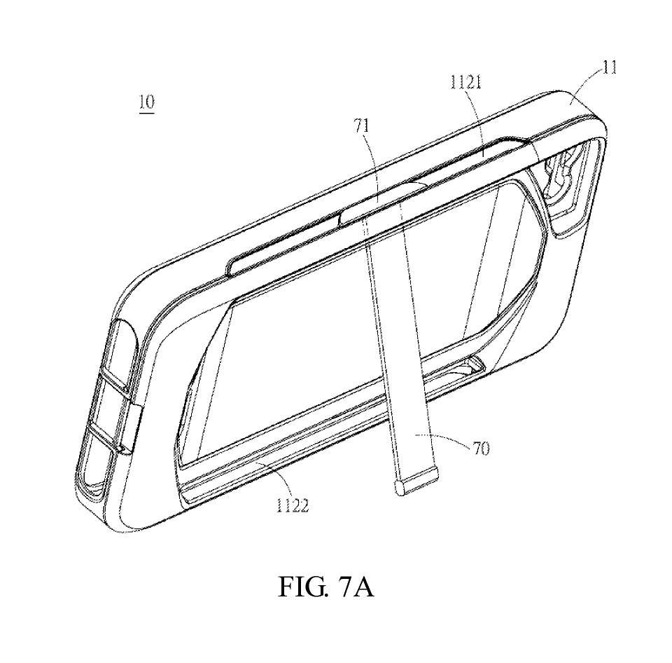

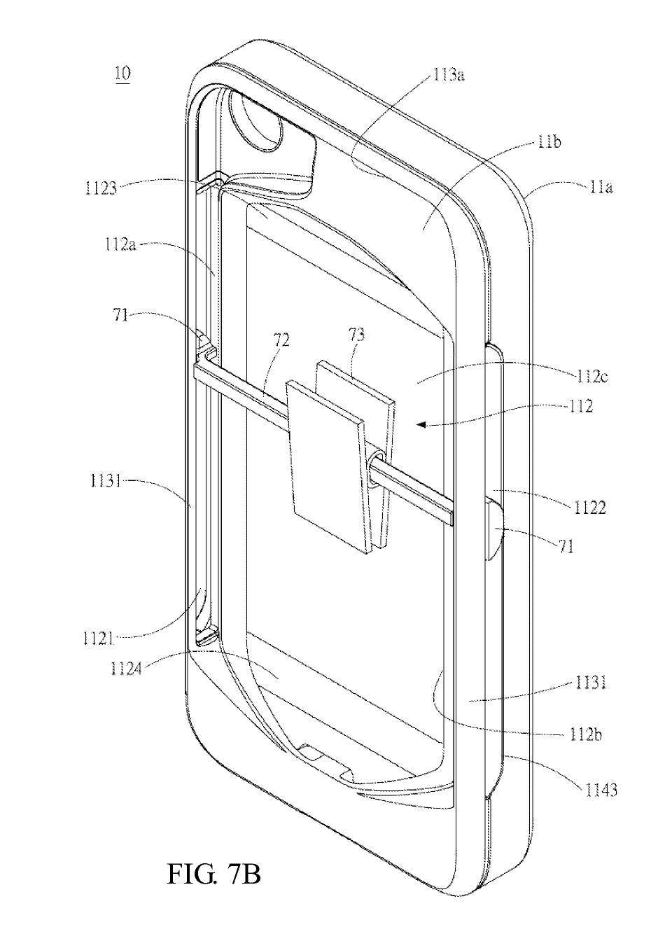

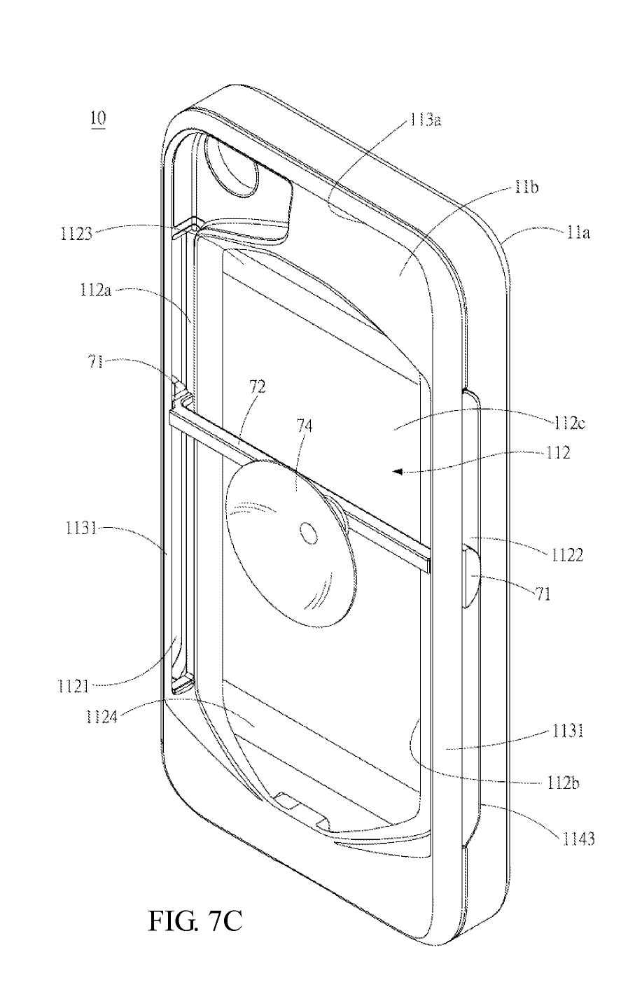

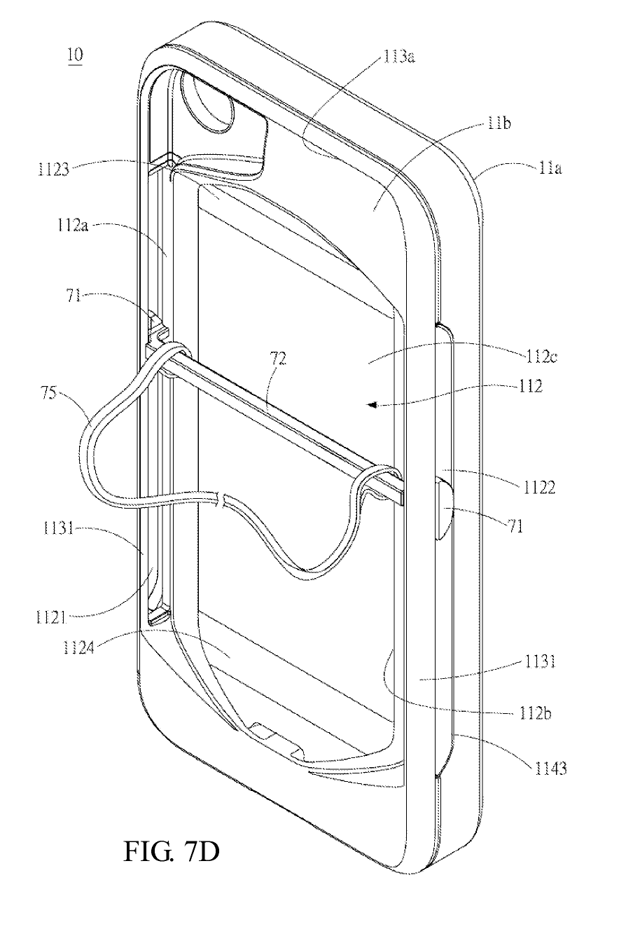

Please refer to FIG. 7A, which illustrates that the fixing auxiliary may be a support element 70 according to an embodiment. The support element 70 has an engaging part 71 at one end thereof. The engaging part 71 is used to connect with the first sliding rail 1121 or the second sliding rail 1122 in a removable manner. Thus, the user can make the support element 70 engaging with the first sliding rail 1121 or the second sliding rail 1122, so that the protective shell 10 can be erected.

Please refer to FIGS. 7B to 7D, which illustrate that the fixing auxiliary may be a hanging element 72 according to another embodiment. The handing element 72 has two engaging parts 71 at the two ends thereof. The two engaging parts 71 are used to connect with the first sliding rail 1121 and the second sliding rail 1122 in a removable manner, respectively. Some accessories may be disposed on the hanging element 72, such as a clip (as shown in FIG. 7B, the protective shell 10 can be placed on the user's belt), a sucker (as shown in FIG. 7C, the protective shell 10 can be fastened in a car), a hanging belt (as shown in FIG. 7D, the protective shell 10 can be hung around the user's neck), etc.

The disclosure may use a first accommodating slot on a protective shell to accommodate a handheld electric apparatus, a fixing auxiliary (such as the strap) is disposed at a second accommodating slot. Through sliding the strap along the sidewall, the strap can be adjusted to be located at a suitable position to fix a carry-on article of a user, such as a card, a business card, an earphone 80 or another mobile phone. Or, when the user uses a photo shooting function, the strap can assist in fixing the handheld electric apparatus. Further, a mobile power supply may also be disposed by use of the second accommodating slot, and charge the handheld electric apparatus. Additionally, a back cover may also be pivoted in the second accommodating slot, and the second accommodating slot may be partitioned into a plurality of accommodating spaces, so the user places carry-on articles conveniently according to categories; furthermore, the inside of the back cover may be a mirror surface to be used and favorably carried by the user, and the mirror surface is protected by the hard material of the outside of the back cover, so as to prevent the mirror surface from rupturing due to collision.

While the disclosure has been described by the way of example and in terms of the preferred embodiments, it is to be understood that the invention need not be limited to the disclosed embodiments. On the contrary, it is intended to cover various modifications and similar arrangements included within the spirit and scope of the appended claims, the scope of which should be accorded the broadest interpretation so as to encompass all such modifications and similar structures.

What is claimed is:

1. A protective shell, applicable to a handheld electric apparatus, comprising:
a main body, having a front face and a back face opposite to each other, comprising:
a first accommodating slot, located at the front face, and used for accommodating the handheld electric apparatus; and
a second accommodating slot, located at the back face, wherein the second accommodating slot comprises a first sidewall and a second sidewall opposite to each other, the first sidewall comprises a first sliding rail, the second sidewall comprises a second sliding rail; and
a fixing auxiliary, disposed at at least one of the first sliding rail and the second sliding rail in a removable manner.

2. The protective shell according to claim 1, wherein the fixing auxiliary is a strap having a first end and a second end opposite to each other, the first end of the strap is disposed at the first sliding rail in a slidable manner, and the second end of the strap is disposed at the second sliding rail in a slidable manner.

3. The protective shell according to claim 2, wherein the strap comprises an elastic strap and two stop blocks connected to two ends of the elastic strap, the first sliding rail and the second sliding rail are both a elongated hole, the elastic strap passes through the elongated holes, and the two stop blocks respectively abut against outsides of the first sliding rail and the second sliding rail.

4. The protective shell according to claim 3, wherein the strap comprises: an elastic strap and multiple stop blocks respectively disposed at the first sliding rail or the second sliding rail in a slidable manner, wherein two of the stop blocks are located on the both ends of the elastic strap, and the other stop blocks are located between the both ends of the elastic strap.

5. The protective shell according to claim 1, wherein the fixing auxiliary is a support element having an engaging part at one end thereof, and the engaging part connects to the first sliding rail or the second sliding rail in a removable manner.

6. The protective shell according to claim 1, wherein the fixing auxiliary is a hanging element having two engaging parts at the two end thereof, and the two engaging parts connect to the first sliding rail and the second sliding rail in a removable manner, respectively.

7. The protective shell according to claim 1, wherein the second accommodating slot further comprises two slopes, the two slopes are respectively disposed at two ends between the first sidewall and the second sidewall, and a comprised angle between the two slopes and a bottom surface of the second accommodating slot is an obtuse angle.

8. The protective shell according to claim 2, wherein the main body comprises:
a rear shell, having a first face and a second face opposite to each other, wherein the first face is disposed with the second accommodating slot; and
a front shell, being a frame body and being connected to the periphery of the second face of the rear shell to form the first accommodating slot, wherein the two sidewalls of the front shell opposite to each other each have a notch, and the two elongated holes are respectively formed between the two notches and the second face of the rear shell.

9. The protective shell according to claim 1, wherein the main body comprises:
a upper frame;
a lower frame, connected with the upper frame in a removable manner; and
a battery holder, located at the inner side of the bottom of the lower frame, such that the battery holder can contain a primary battery when the upper frame and the bottom frame are separated.

10. The protective shell according to claim 9, further comprising: a power connector, comprising:
a first connecting end, correspondingly connected to the battery holder; and
a second connecting end, correspondingly connected to a charging port of the handheld electric apparatus to provide the electrical power of the primary battery to the handheld electric apparatus.

11. The protective shell according to claim 1, wherein the depth of the second accommodating slot is less than the depth of the first accommodating slot.

12. The protective shell according to claim 1, further comprising: a back cover, pivoted on the second accommodating slot, so as to cover a slot notch of the second accommodating slot.

13. The protective shell according to claim 1, further comprising: a rechargeable battery, disposed at the second accommodating slot in a removable manner, wherein the rechargeable battery comprises a power supply terminal, the second accommodating slot further comprises a receiving port disposed corresponding to the power supply terminal.

14. The protective shell according to claim 13, wherein the main body further comprises a power supply port, electrically connected to the receiving port, wherein the protective shell further comprises:
a first connecting end, correspondingly connected to the power supply port; and
a second connecting end, correspondingly connected to a charging port of the handheld electric apparatus to provide the electrical power from the first connecting end to the handheld electric apparatus.

15. The protective shell according to claim 13, further comprises: a wireless power supply module, electrically connected to the receiving port, wherein the protective shell further comprises a power connector, comprising:
a wireless receiver, receiving the electrical power from the wireless power supply module in an electromagnetic induction manner; and
a second connecting end, correspondingly connected to a charging port of the handheld electric apparatus to provide the electrical power from the wireless receiver to the handheld electric apparatus.

16. The protective shell according to claim 1, wherein the main body further comprises an opening disposed corresponding to a connection port of the handheld electric apparatus and a dust proof cover connected with the opening.

17. The protective shell according to claim 1, wherein the bottom of the second accommodating slot is hollow.
